(19) United States
(12) Patent Application Publication
(10) Pub. No.: US 2009/0108904 A1
(43) Pub. Date: Apr. 30, 2009

(54) Shifting of a voltage level between different voltage level domains

(76) Inventor: James David Shiffer, II, Pleasanton, CA (US)

Correspondence Address: NIXON & VANDERHYE, PC, 901 NORTH GLEBE ROAD, 11TH FLOOR, ARLINGTON, VA, 22203, US

(21) Appl. No.: 11/976,437

(22) Filed: Oct. 24, 2007

(51) Int. Cl. H03L 5/00

(52) U.S. Cl. 327/333

(57) ABSTRACT

A voltage level shifter for receiving a digital signal from a first voltage domain and converting said signal to a digital signal in a second voltage domain is disclosed. The voltage level shifter comprises: an input for receiving said digital signal from said first voltage domain; a device connected to said input of said voltage level shifter for receiving said digital signal from said first voltage domain and for outputting a digital signal in said second voltage domain, said device being powered by said second voltage domain; a first switching device arranged to connect a high level voltage source of said second domain to an input of said device in response to said input digital signal having a high level and to isolate said high level voltage source of said second domain from said input of said device in response to said input digital signal having a low level; and a second switching device arranged between said voltage level shifter input and said input of said device for inhibiting current flow from said high level voltage source of said second domain to said voltage level shifter input in response to a high level signal at said voltage level shifter input and for allowing current flow in both directions between said voltage level shifter input and said input of said device in response to said voltage level shifter input having a low level signal.

### BACKGROUND OF THE INVENTION

1. Field of the Invention

The field of the invention relates to level shifters for shifting the voltage level between voltage domains.

2. Description of the Prior Art

Voltage level shifters are known that convert a signal from one voltage domain to a signal suitable for another voltage domain. This allows circuits that work at different voltage levels to interface with each other.

FIG. 1 shows a conventional TTL to CMOS level shifter used for converting the voltages required for TTL to those required for CMOS. This voltage level shifter works very well provided you know the voltages of the input and output supplies. This is because it allows you to tune the size of transistor p3 so that it drops VDD down to VDDI. This is necessary as if VDDI is much less that VDD then when VDDI is input to inverter 10 p1 will not be completely off and therefore there will be leakage through this inverter. If the size of p3 is tuned such that the voltage drop across it in its diode mode is VDD-VDDI then VDDI will be present at the source of p1 and at the gate of p1 and thus, there will be no leakage across this transistor.

However, standard cells now require support for both VDDI and VDD being variable. In such a situation, it is not possible to tune p3 to avoid leakage through inverter 10 where VDD is much greater than VDDI. Furthermore, if you make the voltage drop too large across p3 then the level shifter won't work where VDD is less than VDDI.

FIG. 2 shows an alternative level shifter according to the prior art that is operable for variable values of VDD and VDDI. This consists of a balanced circuit 20 with the input domain receiving signals from a VDDI domain via an inverter powered by VDDI. The balanced circuit is powered by VDD and thus, outputs signals in the VDD domain via an inverter powered by VDD. The balanced circuit 20 functions such that if a signal on one side is slightly higher than a signal on the other the circuit flips. Thus, a one at input IN is input as a zero to the balanced circuit via inverter 40 and if the circuit is currently holding a one then this will cause it to flip to a zero. This is then output as a one via the inverter 50 and as the balanced circuit and the inverter are powered at VDD this one is at the VDD level. Thus, a one input in the VDDI domain is output as a one in the VDD domain. The circuit could have an enable signal (not shown) which could be set to hold the circuit output at a given value if it is turned off this would allow the input circuit to float without the output signal floating.

Although this circuit works for different values of VDDI and VDD it has a portion of the circuit, inverter 40 powered by VDDI. This means that when building the circuit an nwell tied to VDD and an nwell tied to VDDI are required if the problem of latchup is to be avoided when VDDI powers up before VDD.

This problem is disclosed with respect to FIGS. 3a and 3b. FIG. 3a shows an nwell 52 connected to VDD and the p plus 58 part of the substrate connected to VDDI. This arrangement results in a parasitic diode 55 between the p substrate 58 and the nwell 52. If VDDI powers up before VDD this forward biases this diode 55 and the system might latch up. To avoid this a circuit structure shown schematically in FIG. 3b is provided. In this circuit there is an nwell 60 tied to VDD and an nwell 70 tied to VDDI, this means that there is no parasitic diode present. However, as these circuits are generally laid in a block comprising standard cells, the cell 80 to produce such a circuit will need to be large as the nwell tied to VDDI cannot be at the edge of the circuit as the edge of the cell generally shares its nwell neighbouring cells and these are all powered in the VDD domain. Thus, a separate nwell 70 tied to VDDI is provided in the center of the cell 80 and this nwell 70 causes cell 80 to be large. This is because there needs to be a certain distance between nwells tied to different voltage levels.

Embodiments of the present invention seek to provide a voltage level shifter that operates for different voltage levels and that does not require two nwells.

### SUMMARY OF THE INVENTION

A first aspect of the present invention provides a voltage level shifter for receiving a digital signal from a first voltage domain and converting said signal to a digital signal in a second voltage domain, said voltage level shifter comprising: an input for receiving said digital signal from said first voltage domain; a device connected to said input of said voltage level shifter for receiving said digital signal from said first voltage domain and for outputting a digital signal in said second voltage domain, said device being powered by said second voltage domain; a first switching device arranged to connect a high level voltage source of said second voltage domain to an input of said device in response to said input digital signal having a high level and to isolate said high level voltage source of said second domain from said input of said device in response to said input digital signal having a low level; and a second switching device arranged between said voltage level shifter input and said input of said device for inhibiting current flow from said high level voltage source of said second domain to said voltage level shifter input in response to a high level signal at said voltage level shifter input and for allowing current flow in both directions between said voltage level shifter input and said input of said device in response to said voltage level shifter input having a low level signal.

The present invention recognises that a device that is powered in one voltage domain may not always correctly recognise a digital input signal in a different voltage domain. The level shifter of the present invention comprises a device powered in the second voltage domain and therefore outputting signals in the second voltage domain. It also comprises a switching device that in response to a high signal in the first voltage domain provides a high signal in the second voltage domain to this device. Thus, this device receives its high input signal in the domain it operates in and has no problem recognising or responding to this signal. However, the present invention also recognises that there is a potential problem here as there is a potential leakage path between the input to the voltage level shifter from this high level second voltage domain signal. This could be a problem if the first voltage domain is lower than the second voltage domain. This potential problem is addressed by providing a further switching device arranged between the voltage level shifter input and the input of the device, this further switching device inhibits current flow from the device to the voltage level shifter input. Thus, when the device input is tied to the high level of the second voltage domain when the input signal is high, this further switching device does not allow current to flow from the device held at this high level to the input. When the input signal to the voltage level shifter is low this device provides a simple connection such that current can flow in either direction. This is OK from a leakage point of view as when the voltage signal is low the first switching device isolates the high level voltage source of the second domain from the input and thus, there is not a potential for current flow from this device to the input.

In some embodiments, said second switching device comprises an NMOS transistor, a gate of said NMOS transistor being connected to a high level signal of said first voltage domain, such that said NMOS transistor inhibits current flow in a direction from said device input to said voltage level shifter input, while allowing current flow from said voltage level shifter input to said device input in response to a high level signal at said voltage level shifter input and is switched on and allows current to flow in either direction in response to a low level signal of said first voltage domain being input to said voltage level shifter.

The use of an NMOS transistor on the input with its gate connected to a high level of the first voltage domain means that when the input to the voltage level shifter is at this high level then the NMOS transistor is connected as a diode and will not allow current to flow through it towards this input. Thus, at this point if the input to the device is connected to the second voltage domain and the second voltage domain is higher than the first voltage domain there can be no current flow into the input which protects the input and saves leakage current. When the input to the voltage level shifter goes down then the NMOS transistor is turned on and allows current to flow in either direction. This is a practical solution to the problem of isolating the input to the voltage level shifter from the second voltage domain while allowing current to flow in either direction when the input to the voltage level shifter is low. The use of an NMOS transistor with its gated tied to VDDI means that it can be powered by the VDD rail. It is only PMOS devices with source or drains connected to VDDI that need an nwell tied to VDDI. Thus, this device can be built using substrates that are tied to one power domain. Furthermore, as the first voltage domain is only used as reference signal there is no requirement for a sturdy power rail for this voltage as no significant current is drawn.

In some embodiments said gate of said NMOS transistor is connected to a source of said high level signal of said first voltage domain via a buffer device.

It is often undesirable to tie a gate of a device directly to a power supply as power supplies often have peaks in them and this can damage the oxide on the gate layer. Thus, in preferred embodiments the signal input to the gate is input by some sort of buffer device.

In some embodiments, said NMOS transistor comprises an NMOS transistor with a low threshold voltage level.

It is desirable to provide a low threshold voltage level NMOS transistor as this increases the speed of the circuit but does not increase power loss.

In some embodiments, said device comprises a first gate and a second gate arranged in series, said first and second gates being powered by said second voltage domain, and an output of said first gate providing a signal for controlling said first switching device.

Although, the voltage level shifter of an embodiment of the invention can comprise a device having a single gate in preferred embodiments it has two gates. This is so that the output from the first gate which is dependent on the input signal can be used to control the first switching device. This output is not output to an external circuit but merely to the second gate and as such does not draw a load. Thus, the feedback required via the first switching device is not slowed by any load on its control signal.

In some embodiments, said first and second gates comprise respectively first and second inverters.

Two gates are advantageous for the reasons described above, and the the use of inverters as these gates is a particularly advantageous embodiment.

In some embodiments, said first switching device comprises a PMOS transistor connected between a high level voltage source of said second voltage domain and an input to said first inverter, a gate of said PMOS transistor being connected to an output of said first inverter, such that in response to a low signal at said output of said first inverter said PMOS transistor turns on.

Where the two gates are inverters, a PMOS transistor powered by the second voltage domain makes an efficient first switching device as a high signal at the input to the first inverter will produce a low signal at its output, this low signal is then sent to the gate of the PMOS transistor turning this device on. This will cause the input of this inverter to be pulled up towards the high level of the second voltage domain.

In some embodiments, said first switching device comprises a PMOS transistor with a low threshold voltage level.

Although a high threshold device could be used as a PMOS transistor a low threshold device has an advantage of a low resistance and therefore it pulls the input to the inverter up closer to the level of the second voltage domain this helps reduce leakage through the inverter.

In some embodiments, said first inverter comprising a PMOS transistor stacked on an NMOS transistor, said input digital signal being input to gates of said PMOS and NMOS transistors and an inverted signal being output from a junction between said PMOS and NMOS transistors; wherein said first switching device is arranged to connect a high voltage level source of said second domain to a gate of said PMOS transistor of said first inverter in response to a low inverted signal at said output of said first inverter and not to make said connection in response to a high inverted signal at said output of said first inverter; and said second switching device is arranged between said voltage level shifter input and said gate of said PMOS transistor, said gate of said NMOS transistor being directly coupled to said voltage level shifter input.

In some embodiments, the inverter is formed of a stacked PMOS and NMOS transistor. These transistors are powered by the second voltage domain and if the first voltage domain has an input signal that is significantly lower than the second voltage domain then when this is high it may not be sufficient to turn the PMOS transistor off completely and thus there will be a large leakage current through the inverter. The use of the first switching device to pull the input up towards the second voltage domain enables this PMOS transistor to be securely turned off in all circumstances and reduces this leakage current.

In some embodiments, the first voltage domain may have a high level signal that is higher than the high level signal of the second voltage domain, however, in other embodiments the second voltage domain has a high level signal that is higher than the high level signal of the first voltage domain. Many of the potential problems of voltage level shifters arise when the second voltage domain is higher than the first voltage domain and thus, embodiments of the present invention are particularly advantageous in this circumstance.

In some embodiments, said NMOS transistor of said first inverter is larger than said PMOS transistor of said first inverter.

In the case that the first voltage domain has a much lower high level signal than the second voltage domain it may be that when it is input to an inverter consisting of stacked PMOS and NMOS transistors it is not sufficient to drive the output low enough to turn the first switching device on. In order to ensure that this does not happen the NMOS transistor can be made larger than the PMOS transistor thereby ensuring that the voltage at the output is closer to the low voltage rail than it is to the high voltage rail.

In some embodiments, said first inverter comprises at least one further PMOS transistor said at least one further PMOS transistor being arranged as a stack on top of said PMOS transistor.

It may be that it is not appropriate to vary the size of the transistors in a particular design and in such a case rather than making the PMOS transistor smaller than the NMOS transistor a stack of PMOS transistors can be used to ensure that the node between the PMOS transistors and the NMOS transistors is pulled close to the low voltage rail.

In some embodiments said PMOS transistor of said first inverter comprises a high threshold device.

An alternative solution to the problem arising from the first voltage domain having a lower high level signal than the second voltage domain is to make the PMOS transistor of the stack a high threshold voltage device. This helps bring the voltage at the output to the inverter closer to the low voltage rail than it is to the high voltage rail.

In some embodiments, said first inverter comprises a further PMOS transistor connected as a diode and arranged between said PMOS transistor and said high level power source of said second voltage domain.

A further solution to the above problem could be to provide a PMOS transistor arranged as a diode on top of the PMOS transistor of the inverter. This ensures a voltage drop across it and the output of the first inverter is pulled lower.

A further aspect of the present invention provides a method of converting an input digital signal in a first voltage domain to a digital signal in a second voltage domain comprising: inputting a digital signal in said first voltage level domain to a device that is powered by said second power domain; outputting a signal in said second voltage domain from said device; wherein in response to said input digital signal having a high level said method comprises the further steps of switching a first switching device to connect a high level voltage source of said second domain to an input of said device; and controlling a second switching device arranged between said voltage level shifter input and said input of said device to inhibit current flow from said high level voltage source of said second domain to said voltage level shifter input in response to a high level signal at said voltage level shifter input and to allow current flow in both directions between said voltage level shifter input and said input of said device in response to said voltage level shifter input having a low level signal.

A yet further aspect of the present invention provides a voltage shifting means for receiving a digital signal from a first voltage domain and converting said signal to a digital signal in a second voltage domain, said voltage level shifting means comprising: an input means for receiving said digital signal from said first voltage domain a conversion means connected to said input means of said voltage level shifting means for receiving said digital signal from said first voltage domain and for outputting a digital signal to said second voltage domain, said conversion means being powered by said second voltage domain; a first switching means for connecting a second domain voltage source means for supplying a high level voltage of said second domain to an input of said conversion means in response to said input digital signal having a high level and for isolating said second domain voltage source means from said input of said conversion means in response to said input digital signal having a low level; and a second switching means arranged between said voltage level shifter input means and said input of said conversion means for inhibiting current flow from said second domain voltage source means to said input means in response to a high level signal at said input means and for allowing current flow in both directions between said input means and said input of said conversion means in response to said voltage level shifter input having a low level signal.

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 shows a voltage level shifter for converting signals from TTL circuits to signals suitable for CMOS circuits according to the prior art;

FIG. 2 shows a voltage level shifter for shifting signals from a first voltage domain to signals suitable for a second voltage domain according to the prior art;

FIG. 3a shows a parasitic diode produced by an nwell connected to a high voltage level and a p substrate connected to a lower voltage level;

FIG. 3b shows a circuit having multiple nwells;

FIG. 4 shows a voltage level shifter according to an embodiment of the present invention;

FIG. 5 shows a voltage level shifter according to an alternative embodiment of the present invention;

FIG. 6 shows a voltage level shifter with the first inverter comprising a stack of PMOS transistors on an nmos transistor;

FIG. 7 shows a voltage level shifter with an enable signal that clamps the circuit low; and

FIG. 8 shows an alternative embodiment of the present invention with an enable signal that clamps the circuit high.

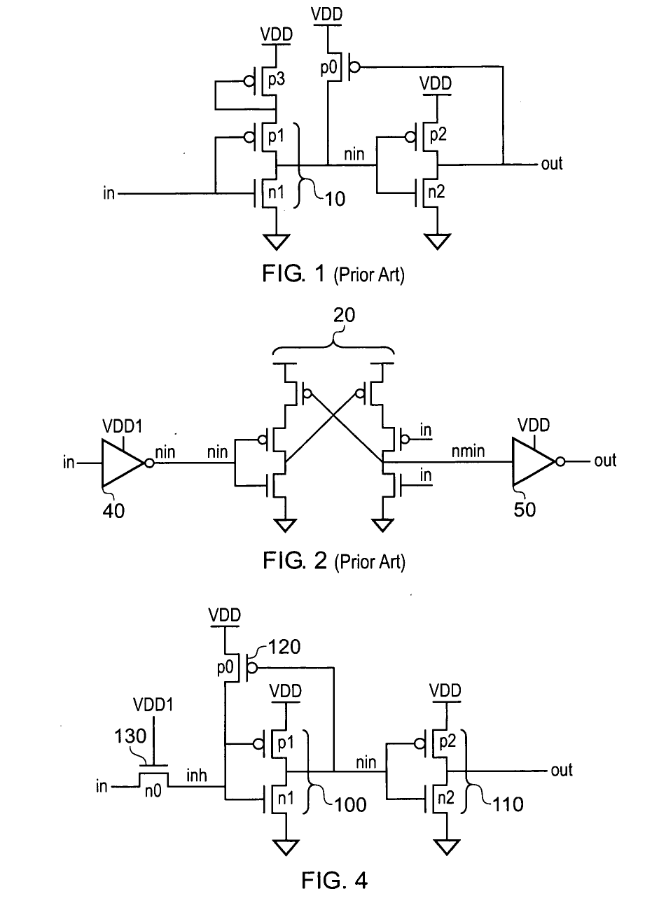

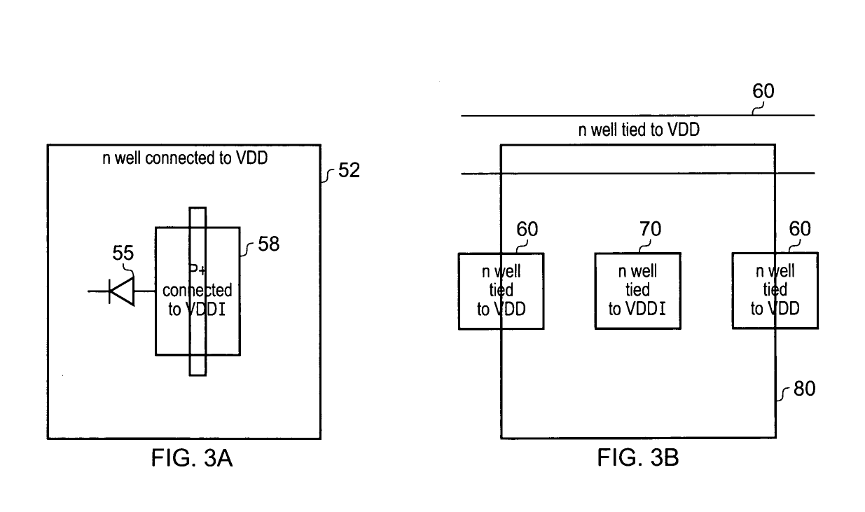

### DESCRIPTION OF THE PREFERRED EMBODIMENTS

FIG. 4 shows a voltage level shifter according to an embodiment of the present invention. It comprises an input in for receiving a digital signal in a first voltage domain with a high voltage level of VDDI and an output out for outputting a signal in a second voltage domain with a high voltage level of VDD. The circuit comprises a first inverter 100 comprising a PMOS transistor p1 and an NMOS transistor n1 and a second inverter 110 comprising a PMOS transistor p2 and an NMOS transistor n2. These two inverters act to receive an input signal invert it to produce nin and then invert nin to produce an output signal out. As they are powered by the second voltage domain VDD, the signal they output is in this voltage domain. In addition to these two inverters 100 and 110 the voltage level shifter also comprises two switching devices 120 and 130. Switching device 120 comprises a PMOS transistor connected between the output of the first inverter and its input. This PMOS transistor is powered by the second voltage domain VDD. When the signal output from the inverter is low, which occurs in response to the input signal being high, the PMOS transistor is turned on and the input is pulled up towards VDD. This is desirable as if VDDI is significantly lower than VDD then a high VDDI signal may not be sufficient to turn PMOS transistor p1 off. This would result in leakage current. Pulling the input up to VDD ensures that this circuit is turned off as this circuit is powered by VDD. A potential drawback with having this feedback loop is that if VDD is higher than VDDI there is a potential leakage path back into the input from the VDD power rail connected to transistor 120. This is blocked by second switching device 130. This second switching device 130 has a VDDI signal on its gate such that when the input is high at VDDI this NMOS transistor is configured to be a diode and will not allow current flow from in to inh thus, the potential leakage path through transistor 120 to the input signal is blocked. When there is a low input signal then switching device 130 is turned on and allows current flow in both directions. At this point, the inverted input signal nin is high and thus, transistor 120 is turned off and thus, the possible leakage route from the VDD power supply powering transistor 120 is blocked.

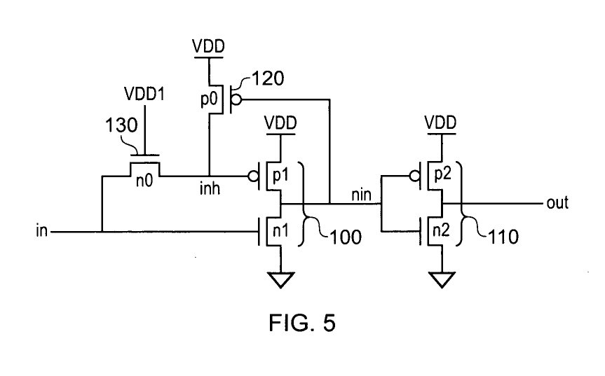

FIG. 5 shows a similar embodiment to that shown in FIG. 4 but in this embodiment the switching device 130 is located on a separate leg to the input to the NMOS transistor n1. This produces a device that acts faster than the device of FIG. 4 as it removes the voltage drop due to the threshold voltage of transistor 130 from the input path of the NMOS transistor n1 when the input is high.

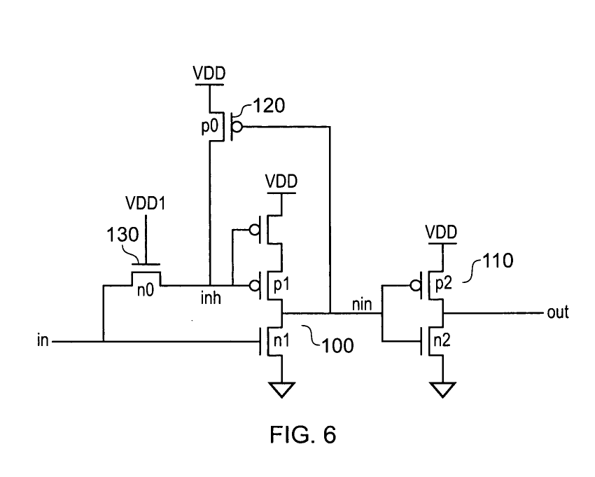

FIG. 6 shows an alternative embodiment where instead of having a single PMOS transistor p1 in the first inverter 100 there is a stack of two PMOS transistors. This means that there is a larger voltage drop across these two transistors than there would be across one, bringing nin closer to ground. Thus, nin is low even if a VDDI 1 is not very high (compared to a VDD 1) and this ensures that the transistor p0 is turned on. However, it will hurt performance when VDD is a low voltage. Alternative embodiments to address the problem that can be caused by VDDI being low compared to VDD have transistor p1 as a high threshold voltage which helps transistor n1 pull nin low. Alternatively, transistor p1 can be smaller than transistor n1 for a similar purpose. This may not be possible in some embodiments where the transistors must be fabricated to the same size. In these cases then a plurality of stacked PMOS transistors are used rather than a single one that is smaller.

In other embodiments, the additional PMOS transistor can be connected as a diode and as this has a known voltage drop across it and it can help to reduce the voltage of nin when in is high.

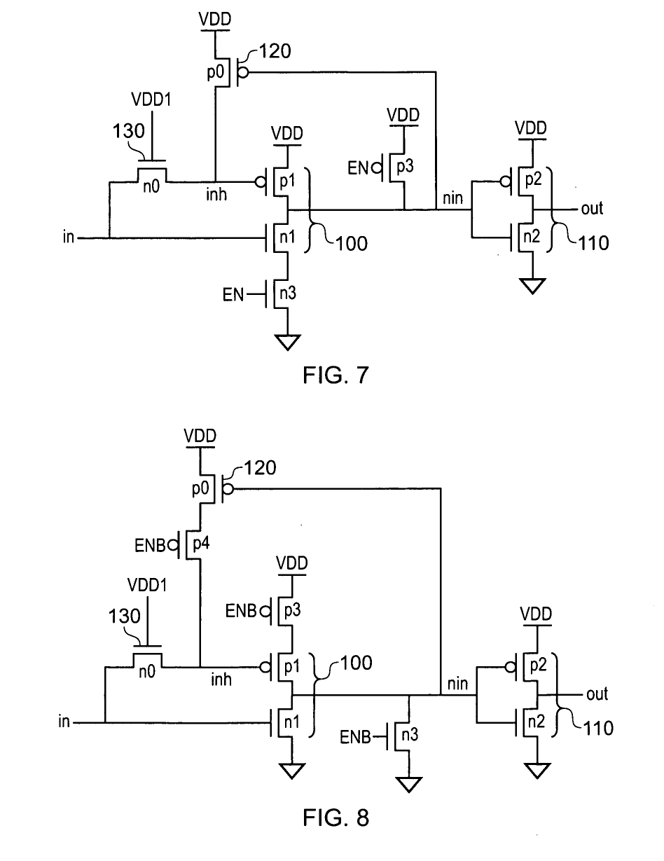

FIG. 7 shows an alternative embodiment with enable signals connected to the circuit. These enable signals help to keep the output of the signal held at a known value when the circuit is in effect off. This allows the input circuit to be switched off and have floating input without having a floating output into the circuits in the second voltage domain. A floating output connected to the second voltage domain could lead to leakage current flowing from these circuits to the circuits of the first voltage domain and thus, should be avoided.

The circuit of FIG. 7 is very similar to the circuit of FIG. 5 except that it has an additional two enable transistors n3 and p3. The transistor n3 is switched off in response to an enable signal and this stops any leakage occurring through inverter 100 when the input is floating. Transistor p3 is switched on by the enable signal and this holds nin high which holds the output low. Thus, there is a known signal at the output of this circuit and the output does not float.

FIG. 8 shows an alternative embodiment in which a low enable signal ENB acts to hold the output high. This circuit like the circuit of FIG. 7 is similar to the circuit of FIG. 5 but has additional transistors p4, p3 and n3. p3 acts as n3 did in the previous example to turn off in response to the ENB signal and thus, stop any leakage through inverter 100. Transistor n3 acts to hold nin low in response to the ENB signal and therefore the output of the circuit is held high and does not float. Transistor p4 acts to switch off in response to the ENB signal and stops any leakage from VDD through p0 which is switched on over n in is low.

It should be noted that in the Figures shown VDDI is shown as being input to the gate of transistor n0. Most CMOS processes discourage or prohibit connecting of power supplies to gates of a transistor. In this case it is not the power supply that is connected but merely a signal at this level. This may be the power supply transmitted through some buffering device. For example this could be done by a cell created externally to the level shifter that buffers the VDDI voltage reference. This has a further advantage that the power supply for VDDI is used only as a reference and thus no sturdy power rail for this power supply is required for this circuit.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims.

I claim:

1. A voltage level shifter for receiving a digital signal from a first voltage domain and converting said signal to a digital signal in a second voltage domain, said voltage level shifter comprising:
an input for receiving said digital signal from said first voltage domain;
a device connected to said input of said voltage level shifter for receiving said digital signal from said first voltage domain and for outputting a digital signal in said second voltage domain, said device being powered by said second voltage domain;
a first switching device arranged to connect a high level voltage source of said second domain to an input of said device in response to said input digital signal having a high level and to isolate said high level voltage source of said second voltage domain from said input of said device in response to said input digital signal having a low level; and
a second switching device arranged between said voltage level shifter input and said input of said device for inhibiting current flow from said high level voltage source of said second domain to said voltage level shifter input in response to a high level signal at said voltage level shifter input and for allowing current flow in both directions between said voltage level shifter input and said input of said device in response to said voltage level shifter input having a low level signal.

2. A voltage level shifter according to claim 1, wherein said second switching device comprises an NMOS transistor, a gate of said NMOS transistor being connected to a high level signal of said first voltage domain, such that said NMOS transistor inhibits current flow in a direction from said device input to said voltage level shifter input, while allowing current flow from said voltage level shifter input to said device input in response to a high level signal at said voltage level shifter input and is switched on and allows current to flow in either direction in response to a low level signal of said first voltage domain being input to said voltage level shifter.

3. A voltage level shifter according to claim 2, wherein said gate of said NMOS transistor is connected to a source of said high level signal of said first voltage domain via a buffer device.

4. A voltage level shifter according to claim 2, wherein said NMOS transistor comprises an NMOS transistor with a low threshold voltage level.

5. A voltage level shifter according to claim 1, wherein said device comprises a first gate and a second gate arranged in series, said first and second gates being powered by said second voltage domain, and an output of said first gate providing a signal for controlling said first switching device.

6. A voltage level shifter according to claim 5, wherein said first and second gates comprise respectively first and second inverters.

7. A voltage level shifter according to claim 6, wherein
said first switching device comprises a PMOS transistor connected between a high level voltage source of said second voltage domain and an input to said first inverter, a gate of said PMOS transistor being connected to an output of said first inverter, such that in response to a low signal at said output of said first inverter said PMOS transistor turns on.

8. A voltage level shifter according to claim 7, wherein said first switching device comprises a PMOS transistor with a low threshold voltage level.

9. A voltage level shifter according to claim 6, wherein
said first inverter comprising a PMOS transistor stacked on an NMOS transistor, said input digital signal being input to gates of said PMOS and NMOS transistors and an inverted signal being output from a junction between said PMOS and NMOS transistors; wherein
said first switching device is arranged to connect a high voltage level source of said second domain to a gate of said PMOS transistor of said first inverter in response to a low inverted signal at said output of said first inverter and not to make said connection in response to a high inverted signal at said output of said first inverter; and
said second switching device is arranged between said voltage level shifter input and said gate of said PMOS transistor, said gate of said NMOS transistor being directly coupled to said voltage level shifter input.

10. A voltage level shifter according to claim 9, said second voltage domain having a high level signal that is higher than a high level signal of said first voltage domain.

11. A voltage level shifter according to claim 9, wherein said NMOS transistor of said first inverter is larger than said PMOS transistor of said first inverter.

12. A voltage level shifter according to claim 9, wherein said first inverter comprises at least one further PMOS transistor said at least one further PMOS transistor being arranged as a stack on top of said PMOS transistor.

13. A voltage level shifter according to claim 9, wherein said PMOS transistor of said first inverter comprises a high threshold device.

14. A voltage level shifter according to claim 9, wherein said first inverter comprises a further PMOS transistor connected as a diode and arranged between said PMOS transistor and said high level power source of said second voltage domain.

15. A method of converting an input digital signal in a first voltage domain to a digital signal in a second voltage domain comprising:
inputting a digital signal in said first voltage level domain to a device that is powered by said second power domain;
outputting a signal in said second voltage domain from said device; wherein
in response to said input digital signal having a high level said method comprises the further steps of
switching a first switching device to connect a high level voltage source of said second domain to an input of said device; and
controlling a second switching device arranged between said voltage level shifter input and said input of said device to inhibit current flow from said high level voltage source of said second domain to said voltage level shifter input in response to a high level signal at said voltage level shifter input and to allow current flow in both directions between said voltage level shifter input and said input of said device in response to said voltage level shifter input having a low level signal.

16. A voltage shifting means for receiving a digital signal from a first voltage domain and converting said signal to a digital signal in a second voltage domain, said voltage level shifting means comprising:
an input means for receiving said digital signal from said first voltage domain
a conversion means connected to said input means of said voltage level shifting means for receiving said digital signal from said first voltage domain and for outputting a digital signal to said second voltage domain, said conversion means being powered by said second voltage domain;
a first switching means for connecting a second domain voltage source means for supplying a high level voltage of said second domain to an input of said conversion means in response to said input digital signal having a high level and for isolating said second domain voltage source means from said input of said conversion means in response to said input digital signal having a low level; and
a second switching means arranged between said voltage level shifter input means and said input of said conversion means for inhibiting current flow from said second domain voltage source means to said input means in response to a high level signal at said input means and for allowing current flow in both directions between said input means and said input of said conversion means in response to said voltage level shifter input having a low level signal.
